(19) United States
(12) Patent Application Publication
(10) Pub. No.: US 2013/0258562 A1
(43) Pub. Date: Oct. 3, 2013

(54) ELECTRONIC DEVICE AND ASSEMBLING METHOD THEREOF

(71) Applicants: HONG FU JIN PRECISION INDUSTRY (ShenZhen) CO., LTD., (US); HON HAI PRECISION INDUSTRY CO., LTD., New Taipei (TW)

(72) Inventor: YUAN-MING WANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/726,560

(22) Filed: Dec. 25, 2012

(30) Foreign Application Priority Data
Mar. 29, 2012 (CN) 201210087691.4

(51) Int. Cl. H05K 13/00; H05K 5/02

(52) U.S. Cl. CPC H05K 13/00; H05K 5/0226
USPC 361/679.01; 29/825

(57) ABSTRACT

An electronic device including a cover, a base, screws and a hinge member is disclosed. The base includes a first shell defining blind holes, and a second shell defining first through holes aligned with blind holes respectively. The hinge member comprises a rotation portion fasten on the cover; and a fixed portion sandwiched between the first shell and the second shell defines second through holes aligned with first through holes respectively. Screws extends through the first through holes, the second through holes and threadedly engages in the blind holes. Inner thread of the second through holes is formed by extension of the screws through the second through holes. The blind holes are configured for receiving debris produced during the extension of the screws through the second through holes to tap the inner thread.

A method for assembling an electronic device is also disclosed.

### BACKGROUND

1. Technical Field

The present disclosure relates to an electronic device and a method for assembling the electronic device.

2. Description of Related Art

Electronic devices are equipped with hinge members for rotatably connecting one member to another. Take the notebook computer for example, it has a hinge member connecting the top cover to the base, thus, the cover can be rotated relative to the base to open or close the notebook computer. Typically, a rotating portion of the hinge member is fixed on the top cover and a fixed portion of the hinge member is fixed on the base via screws, and the hinge member defines a number of through holes having inner thread engaged with outer thread of screws. The inner thread of the through holes is tapped via the specification tools. However, this method adds a process, i.e., the tapping process to the production and thus increases the production cost and may cause delayed production period.

Therefore, what is needed is an electronic device and a assembling method for fastening a hinge member thereof to alleviate the limitations described above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an electronic device showing the upper cover in an open state, in accordance with an exemplary embodiment.

FIG. 2 is an exploded view of the base of the electronic device of FIG. 1.

FIG. 3 is an isometric view of the first shell of the electronic device of FIG. 2.

FIG. 4 is an isometric view of the hinge member of the electronic device of FIG. 1.

FIG. 5 is a partial, exploded, cross-sectional view of the electronic device FIG. 1.

FIG. 6 is a partial cross-section view of the electronic device of FIG. 1.

FIG. 7 is flowchart of a method for assembling an electronic device in according with an exemplary embodiment.

### DETAILED DESCRIPTION

The disclosure is illustrated by way of example and not by way of limitation in the figures of the accompanying drawings in which like references indicate similar elements. It should be noted that references to “a” or “one” embodiment in this disclosure are not necessarily to the same embodiment, and such references mean “at least one”.

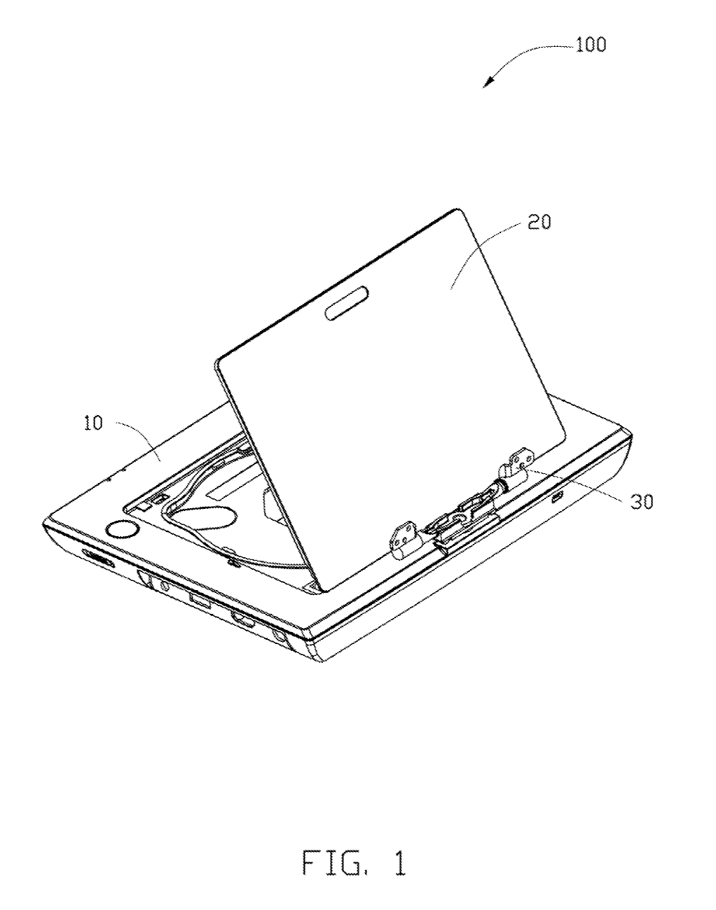

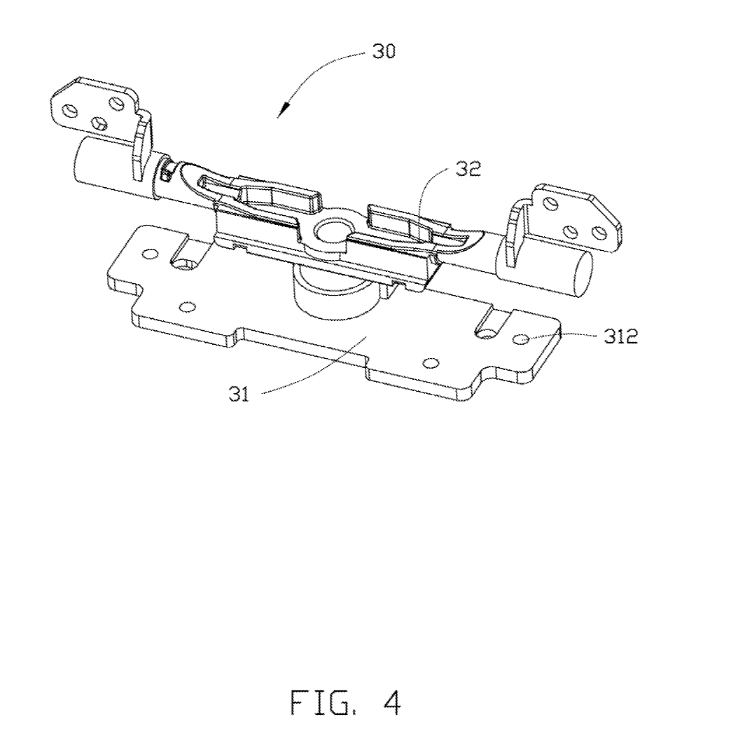

Referring to FIG. 1, an electronic device 100 is disclosed as an exemplary embodiment. The electronic device 100 includes a cover 20, a base 10 and a hinge member 30 connecting the cover 20 to the base 10. The hinge member 30 defines a number of through holes 312 (see FIG. 4) and is fastened on the base 10 via screws which is engaged with inner thread of the through holes 312.

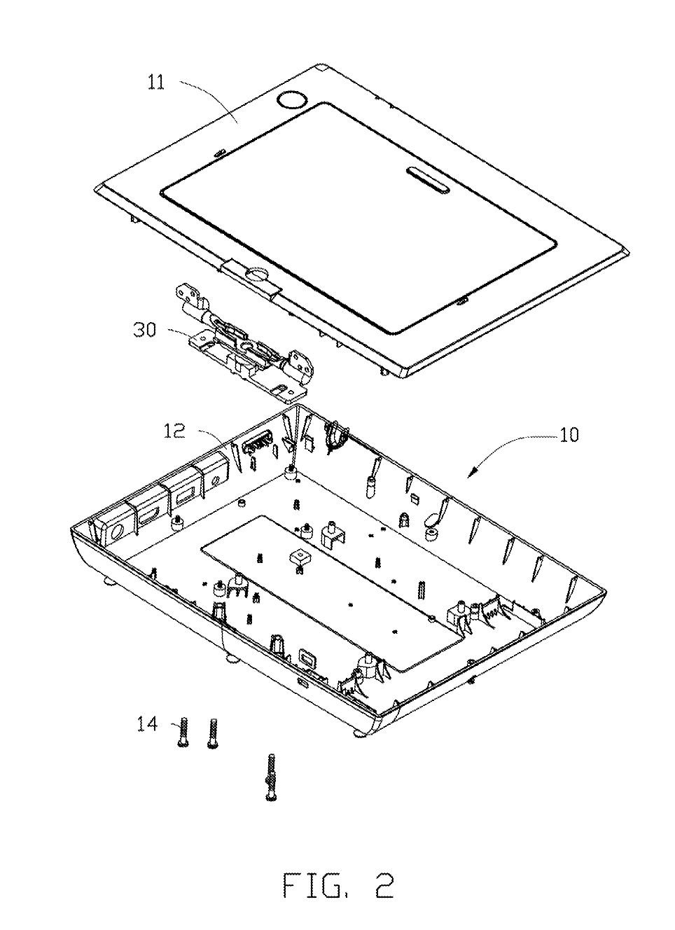

Referring to FIG. 2, the base 20 includes a first shell 11 and a second shell 12 secured to the first shell 11 by screws 14.

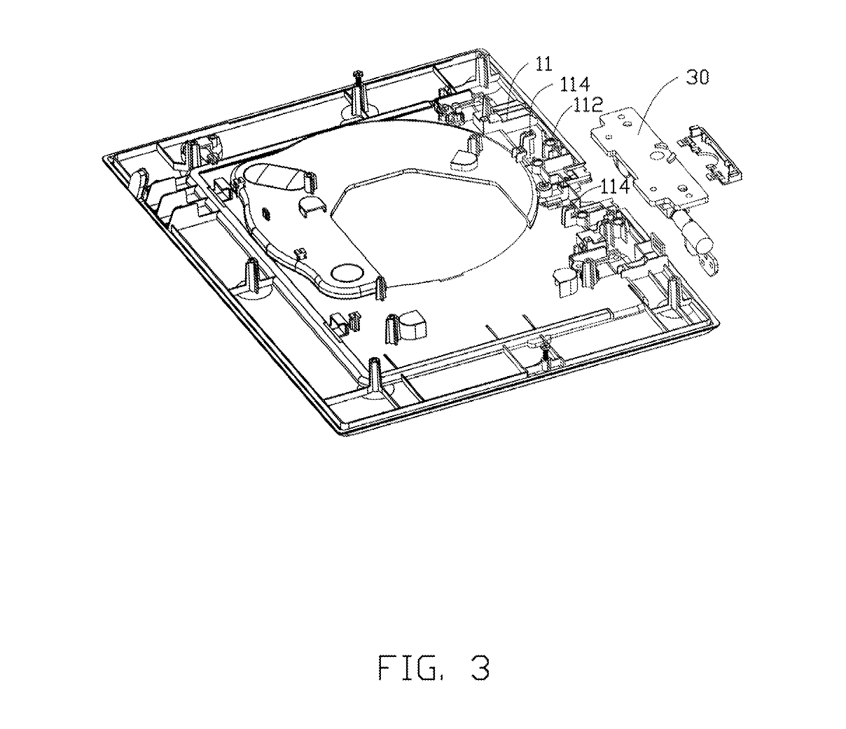

Referring to FIG. 3, the first shell 11 defines a number of cylindrical blind holes 112 and a number of positioning hooks 114 aligned with the hinge member 30.

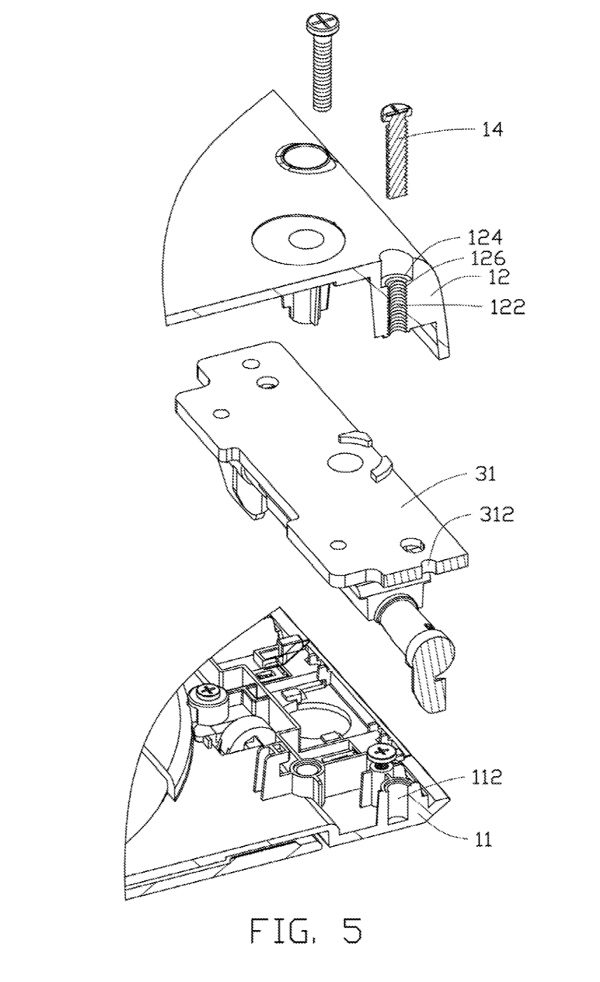

Referring to FIG. 5, the second shell 12 defines several first through holes 122 aligned with corresponding the blind holes 112. In the embodiment, the first through holes 122 have inner threads 126 already formed on walls of the first through holes 122 before assembling the first shell 11 and the second shell 12 together via the hinge member 30 (hereinafter “the assembling process”). In other embodiment, the first through holes 122 have no inner threads but are formed with the inner threads 126 on the walls by the screws 14 during the assembling process. The second shell 12 defines a number of ring positioning stages 124 corresponding to the first through holes 122. FIG. 5 shows only one stage 124. The stage 124 is close to the outside surface of the second shell 12. The diameter of the stage 124 is larger than the diameter of the first through hole 122 and is used for supporting the head of the screw 14. The first through holes 122 are threaded through holes.

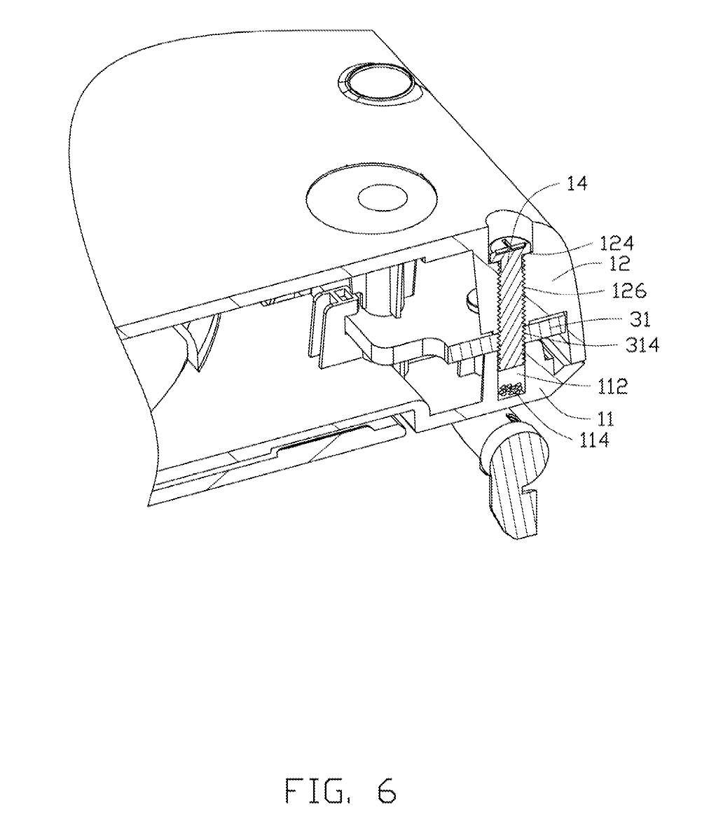

Referring to FIG. 4, the hinge member 30 includes a fixed portion 31 fixed in the base 10 and a rotation portion 32 hinged to the fixed portion 31. The fixed portion 31 is sandwiched between the first shell 11 and the second shell 12. The rotation portion 32 is fixed on the cover 20 via screws. In the embodiment, the fixed portion 31 is plate-shaped and defines a number of second through holes 312 aligned with corresponding the blind holes 112 respectively. FIG. 5 shows a look of the second through hole 312 before the assembling process. FIG. 6 shows another look of the second through holes 312 after the assembling process. During the assembling process, the inner threads 314 are formed on the walls of the second through holes 312 by extension of the screws 14 through the second through holes 312 and engaged with the screws 14.

In assembly, the hinge member 30 is firstly assembled. Then the second through holes 312 are aligned with the blind holes 112 correspondingly, the fixed portion 31 is engaged into the positioning hooks 114 of the first shell 11 to fix the fixed portion 30 on the first shell 11, the fixed portion 31 is fastened to the first shell 11 via screws 14. The first through holes 122 of the second shell 12 are aligned with the second through holes 312 correspondingly, and the second shell 12 is placed on the first shell 11. The screws 14 is extended through the first through holes 122 and the second through holes 312 clockwisely or counterclockwisely to cut inner thread 314 in a inner surface of the second though holes 312. The distal ends of the screws 14 are inserted into the corresponding blind holes 112 with debris 114 generated during cutting the inner thread 314 are accommodated in the blind holes 112. Therefore, the fixed portion 31 is sandwiched between the first shell 11 and the second shell on the base 10.

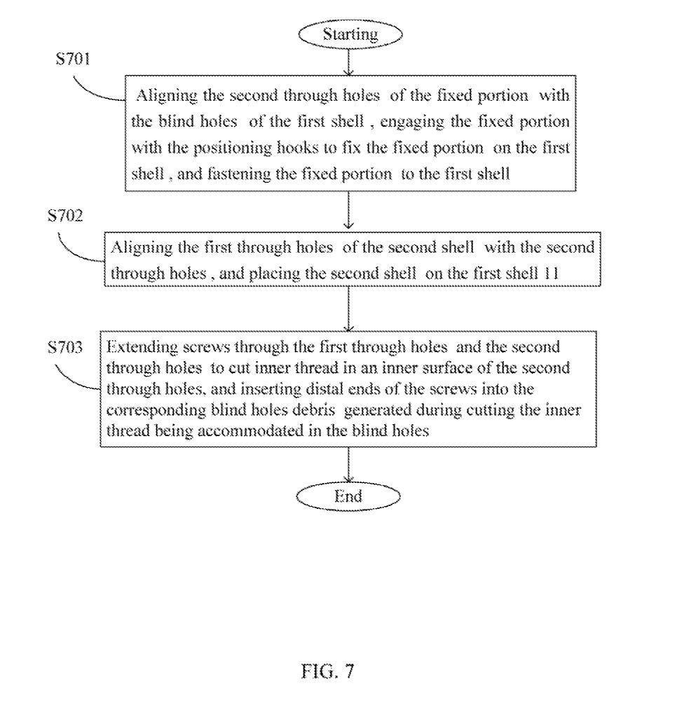

FIG. 7 shows a flowchart of a method for assembling the electronic device 100 thereon in according with an exemplary embodiment. The method includes following steps:

Step S701: aligning the second through holes 312 of the fixed portion 31 with the blind holes 112 of the first shell 11, engaging the fixed portion 31 with the positioning hooks 114 to fix the fixed portion 31 on the first shell 11, and fastening the fixed portion 31 to the first shell 11.

In the embodiment, manually engaging the fixed portion 31 of the hinge member 30 with the positioning hooks 114 of the first shell 11, then aligning the second through holes 312 of the fixed portion 31 correspond respectively to the receiving hooks 114 of the first shell 11, and fastening the fixed portion 31 to the first shell 11 by screws 14.

Step S702: aligning the first through holes 122 of the second shell 12 with the second through holes 312, and placing the second shell 12 on the first shell 11.

Step S703: extending screws 14 through the first through holes 122 and the second through holes 312 to cut inner thread 314 in an inner surface of the second through holes, and inserting distal ends of the screws into the corresponding blind holes debris 114 generated during cutting the inner thread 312 being accommodated in the blind holes 112. Therefore, the fixed portion 31 of the hinge member 30 is sandwiched between the first shell 11 and the second shell on the base 10.

In the embodiment, the first through holes 122 and the second through holes 312 define inner threads when extending the screws 14 clockwisely or counterclockwisely to cut inner thread in an inner surface of the first though holes 122. When the top of the screws 14 are supported by stage 124, the screws 14 are extended to the fixed portion 31. The debris 114 generated when extending the screws 14 through the second through holes 312 fall into the blind holes 112 of the first shell 11 and the distal end of the screws 14 is received in the blind holes 112.

With such configuration, the second through holes 312 are formed with inner threads 314 by the screws 14 when extending the screws 14 through the second through holes 312, and the debris 114 generated during cutting the inner thread 314 drop into the blind holes 112 Therefore, the particular process of tapping the hinge member 30 to form inner threads in the through holes 312 as the conventional way does is avoided and the process of collect the debris 14 is also avoided. Therefore, it speeds up the production process and reduces the cost of assembly.

Although the present disclosure has been described in considerable detail with reference to certain preferred embodiments thereof, the disclosure is not for limiting the scope of the disclosure. Persons having ordinary skill in the art may make various modifications and changes without departing from the scope and spirit of the disclosure. Therefore, the scope of the appended claims should not be limited to the description of the preferred embodiments described above.

What is claimed is:

1. An electronic device comprising:
a cover,
a base comprising a first shell defining a plurality of blind holes, and a second shell secured to the first shell, the second shell defining a plurality of first through holes aligned with the respective blind holes; and
a hinge member comprising:
a rotation portion fastened on the cover; and
a fixed portion hinged to the rotation portion and sandwiched between the first shell and the second shell, the fixed portion defining a plurality of second through holes aligned with the corresponding the first through holes;
a plurality of screws extending through the first through holes, the second through holes and threadedly engaged in the blind holes;
wherein inner thread of the second through holes is formed by extension of the screws through the second through holes; and the blind holes are configured for receiving debris produced during the extension of the screws through the second through holes to tap the inner thread.

2. The electronic device as described in claim 1, wherein a distal end of each of the screws is received in the corresponding blind hole.

3. The electronic device as described in claim 1, wherein the screws are rotated clockwise to tap and engage with the inner thread of the second through holes.

4. The electronic device as described in claim 1, wherein the screws are rotated counterclockwise to tap and engage with the inner thread of the second through holes.

5. The electronic device as described in claim 1, wherein the first through holes are threaded through holes.

6. The electronic device as described in claim 1, wherein the fixed portion is plate-shaped.

7. A method for assembling an electronic device, wherein the electronic device comprises a cover, a base comprising a first shell defining a plurality of blind holes and positioning hooks, and a second shell defining a plurality of first through holes; and a hinge member comprising a rotation portion and a fixed portion hinged to the rotation portion, the fixed portion defining a plurality of second through holes free of inner thread defined therein;
the method comprising:
aligning the second through holes of the fixed portion with the blind holes of the first shell, engaging the fixed portion with the positioning hooks to fix the fixed portion on the first shell, and fastening the fixed portion to the first shell;
aligning the first through holes of the second shell with the second through holes of the fixed portion of the hinge member, and placing the second shell on the first shell;
extending screws through the first through holes and the second through holes to cut inner thread in an inner surface of the second through holes; and
inserting distal ends of the screws into the corresponding blind holes with debris generated during cutting the inner thread being accommodated in the blind holes.

8. The method as described in claim 7, wherein the screws are extended clockwise to cut inner thread in inner surfaces in the first through holes.

9. The method as described in claim 7, wherein the screws are extended counterclockwise to cut inner thread in inner surfaces in the first through holes.
